(19) United States
(12) Patent Application Publication
(10) Pub. No.: US 2010/0001742 A1
(43) Pub. Date: Jan. 7, 2010

(54) Calibration technique

(76) Inventors: Eric W. Strid, Portland, OR (US); Kenneth R. Smith, Portland, OR (US); Roger Hayward, Beaverton, OR (US)

Correspondence Address: CHERNOFF, VILHAUER, MCCLUNG & STENZEL, LLP, 601 SW Second Avenue, Suite 1600, PORTLAND, OR, 97204-3157, US

(21) Appl. No.: 12/456,118

(22) Filed: Jun. 10, 2009

Related U.S. Application Data
(60) Provisional application No. 61/131,907, filed on Jun. 13, 2008.

(51) Int. Cl. G01R 35/00

(52) U.S. Cl. 324/601

(57) ABSTRACT

The tolerance of Short-Open-Load (SOL) and Short-Open-Load-Reflect (SOLR) VNA calibration for variability in probe position is improved by using load and short calibration structures having impedance elements with a length at least two times the probe contact pitch and a width at least two times the sum of the combined pitches of the probe contacts.

### CROSS-REFERENCE TO RELATED APPLICATIONS

This application claims the benefit of U.S. Provisional App. No. 61/131,907, filed Jun. 13, 2008.

### BACKGROUND OF THE INVENTION

The present invention relates to probe measurement systems and, more particularly, to a technique for calibrating a probe measurement system and/or a test contactor that is tolerant of variability in the relative alignment of the probe and a calibration standard.

A probe measurement system typically comprises test instrumentation that is connected to a probe that enables temporary connection of the test instrumentation and the electrical network of a device under test (DUT). A Vector Network Analyzer (VNA) is the test instrument that is commonly used for electrical network measurements at frequencies greater than 1 gigahertz (GHz). A VNA comprises a source of high frequency signals (RF source) and a plurality of measurement receivers. The RF source provides a stimulus, in the form of signals in the radio, microwave and millimeter-wave frequency bands, referred to herein collectively as RF signals, to at least one of the port(s) of the DUT and measures the response of the DUT to the stimulus. Directional couplers or bridges of the measurement receivers pick off the forward and reverse waves traveling to and from the ports of the DUT. The signals are down converted in intermediate frequency sections of the measurement receivers and filtered, amplified and digitized for further processing and display. The VNA measures scattering parameters or S-parameters, vector ratios, comprising a magnitude and a phase component, of the energy that is reflected and transmitted by the DUT which characterize the linear behavior of the DUT.

VNA calibration is used to correct for systematic errors in the measurement system and to define a reference plane that specifies where the probe measurement system ends and where the DUT begins. Systematic errors are the result of the non-ideal natures of the VNA itself and of the cables, waveguides and probes that are used to conductively connect the VNA and the DUT. VNA calibration is a process of stimulating one or more calibration standards, elements having known or partly known characteristics and measuring the response. A deviation from the expected response of the calibration standard is determined, enabling mathematical correction of subsequent measurements of the DUT and accurate determination the DUT's properties. The calibrated measurement system can be characterized as an ideal VNA with an error adapter network that models the probing system's non-ideal characteristics. The accuracy of measurements with a probing system is determined by the repeatability of the measurement system, the technique used in calibration and the accuracy of the description of the calibration standards.

Several techniques can be used for probing system calibration including the Short-Open-Load-Thru (SOLT), the Line-Reflect-Match (LRM), and the Thru-Reflect-Line (TRL) techniques. The names of the techniques designate the particular set of calibration standards that are used in the calibration technique. The calibration standards used in probing system calibration comprise impedance elements that are typically fabricated on the wafer with the DUT or on a separate impedance standard substrate (ISS). Calibration standards utilized in VNA calibration commonly include: a Short, a short circuit conductively interconnecting the signal and ground contacts of a probe; an Open, an open circuit between the ground and signal contacts, commonly accomplished by raising the contacts of the probe or contacting a non-conductive area of a substrate; a Load, a resistive load, commonly 50 ohms (Ω), that interconnects the signal and ground contacts; and a Thru, a transmission line that connects the corresponding signal and ground contacts of two probes that are engageable with the two ports of a two port DUT. For example, the most commonly used calibration technique, the SOLT technique, is a combination of two one-port Short-Open-Load calibrations with additional measurements of a Thru standard to complete the calibration for a two-port DUT.

A fundamental and on-going complication of the use of planar impedance elements in calibrating a probe system is that the arrangement, relative alignment and angle of incidence of the patterned metal and resistive elements comprising a calibration standard effect the measured impedance of the calibration standard. For example, the SOLT, LRM and TRL techniques require a “well behaved” thru. Referring to FIG. 1, this condition is relatively easy to satisfy when the Thru 20 is for calibration of a DUT that has ports on opposite sides of the device. However, it is difficult to fabricate a well behaved Thru 22 for calibrating a DUT with ports that are positioned orthogonally, as illustrated in FIG. 2. The impedance element 24 for an orthogonal Thru is considerably longer than the straight version of a Thru and includes a right-angle bend. Regardless of how carefully the right angle bend is mitered, the discontinuity typically gives rise to a slot-line mode, a leaky parallel-plate mode and a surface wave mode. A second mode, radiation or additional parasitic impedance usually produces a behavior that is DUT dependent and which is not accounted for in the calibration, leading to inaccuracy in measurements of the DUT.

In addition, to obtain accurate measurements for calibrating the probing apparatus, each probe tip must be very carefully and accurately placed on the calibration standard because the impedance of a calibration standard is very dependent on the position of each of the probe tips. As illustrated in FIGS. 3A and 3B, a 3 mil (75 μm) longitudinal change in the overlap of the probe contacts and the impedance element of the Thru calibration standard 24 can produce a significant change in the inductance and the delay of the transmission line comprising the Thru standard.

Calibration of wafer probe cards; including membrane probes, such as those disclosed by Gleason et al, U.S. Pat. No. 6,256,882, that include several probe tips is even more difficult. Wafer probe cards can include 100 or more probe tips each of which must be accurately positioned on respective elements of the calibration standard. Providing a properly trimmed connection between the numerous contact areas on the ISS or an on-wafer calibration standard makes the design and construction of the calibration standards extremely difficult.

What is desired, therefore, is a technique for calibrating a VNA probe measurement system that is tolerant to variability in the position of the probe tips and the calibration standard.

### BRIEF DESCRIPTION OF THE DRAWINGS

FIG. 1 is a schematic illustration of a Thru calibration standard engaged by a pair of probes.

FIG. 2 is a schematic illustration of an orthogonal Thru calibration standard engaged by a pair of probes.

FIG. 3A is a schematic illustration of a Thru calibration standard engaged by a pair of probes in a first orientation.

FIG. 3B is a schematic illustration of the Thru calibration standard of FIG. 3A engaged in a second orientation by the pair of probes.

FIG. 4 is a perspective illustration of a probe measurement system.

FIG. 5 is a top view of an exemplary calibration standard and an exemplary probe tip.

FIG. 6 is a schematic diagram of a calibrated probe measurement system.

FIG. 7 is a schematic diagram of an error model for a probe measurement system.

FIG. 8 illustrates a test contactor for package testing.

FIG. 9 illustrates a patterned test substrate.

FIG. 10 illustrates an auto probing probe station.

### DETAILED DESCRIPTION OF PREFERRED EMBODIMENTS

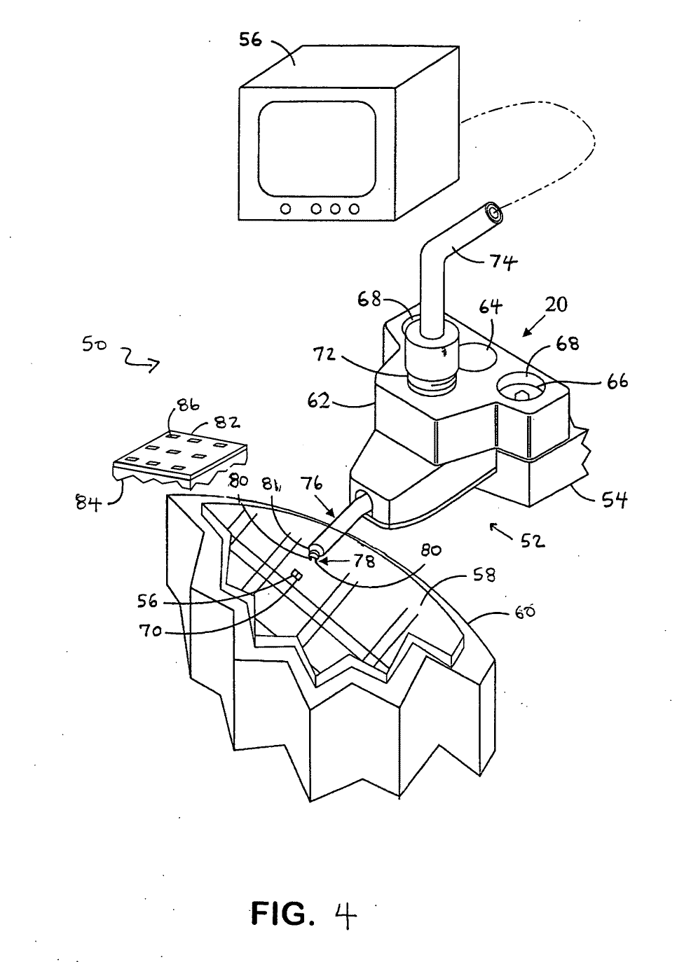

Referring in detail to the drawings where similar parts are identified by like reference numerals, and, more particularly to FIG. 4, a probe measurement system 50 typically comprises a probe 52 that is communicatively connected to a test instrument 56. The probe is typically designed to be mounted on a probe-supporting member 54 of a wafer probe station so as to be in suitable position for probing an electrical network on a device-under-test (DUT), such as an individual component 56 on a wafer 58. In this type of application, the wafer is typically supported on the upper surface of a chuck 60 which is part of the same probe station. The probe 52 includes a primary support block 62 which is suitably constructed for connection to the probe-supporting member. To effect this connection, a round opening 64 that is formed on the support block is snugly fitted, slidably, onto an alignment pin (not shown) that projects upward from the probe-supporting member, and each of a pair of fastening screws 66 are inserted into corresponding countersunk openings 68 in the support block and threaded into engagement with a respective threaded opening in the probe-supporting member. Ordinarily an X-Y-Z positioning mechanism is provided, such as a micrometer knob assembly, to effect movement between the supporting member and the chuck so that the contacts 80, 81 of the probe can be brought into pressing engagement with probe pads 70 of the DUT on the surface of the wafer. The probe pads comprise the ports of the electrical network that comprises the DUT.

The exemplary wafer probe 52 depicted has an input port which comprises a coaxial cable connector 72. This connector enables the external connection of an ordinary coaxial cable 74 to the wafer probe so that a well-shielded high frequency transmission channel can be established between the wafer probe and the test instrumentation. At frequencies greater than 67 GHz, the transmission channel connecting the probe and the test instrumentation commonly comprises a waveguide.

A semi-rigid, second portion of coaxial cable 76 is electrically connected at its rearward end to the coaxial cable connector 72 affixed to the probe. Before being connected to the coaxial cable connector, the second cable portion is bent at first and second intermediate lengths so that an upwardly curving 90° bend and a downwardly curving 23° bend, respectively, are formed in the cable and a semi-cylindrical recess is formed in the cable adjacent its forward end to which a probe tip 78, including conductive contacts 80, 81, is affixed. The forward end of the coaxial cable is freely suspended, supported by the fixed rearward end, and serves as a movable support for the probe tip at the probing end of the probe.

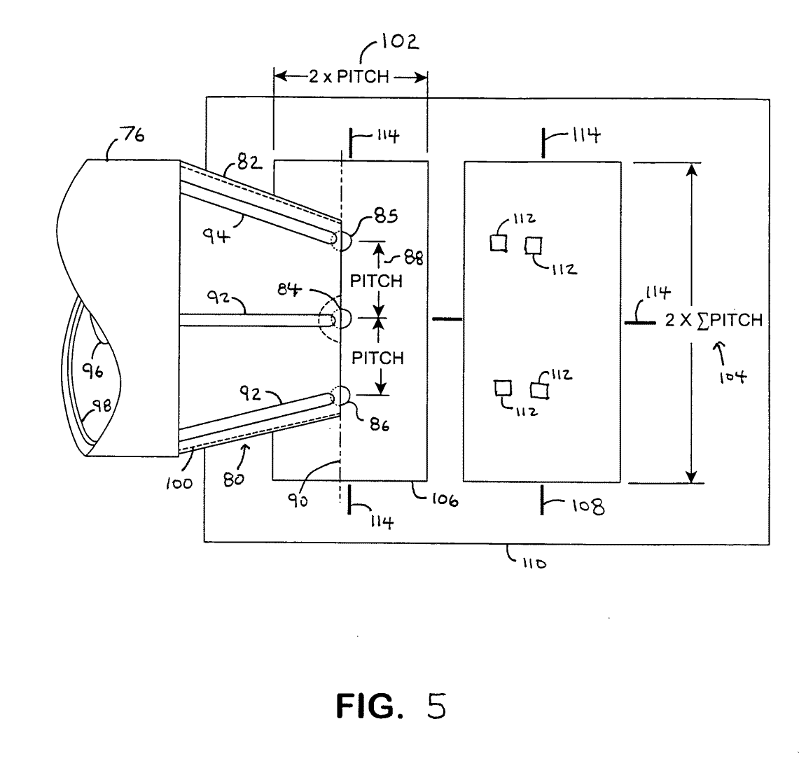

Referring to FIG. 5, a probe tip 80 typically comprises a probe contact supporting substrate 82 that is affixed to the second portion of coaxial cable 76 or other probe tip supporting element, such as a waveguide. For example, Gleason et al., U.S. Pat. No. 6,815,963 B2, disclose a probe tip comprising a dielectric substrate that is attached to a shelf cut in the underside of the probe tip supporting portion of coaxial cable. The probe tip typically extends in the direction of the longitudinal axis of the coaxial cable 76, waveguide or other probe tip supporting element and a plurality of probe contacts, for example probe contacts 84, 85, 86, are typically arranged in a linear array proximate the distal end of the substrate. The centroids of the contacting portions of the respective probe contacts are spaced apart by a pitch dimension 88 along a contact axis 90 that extends substantially normal to the longitudinal axis of the probe tip supporting element. The pitch of the contacts, the lateral center-to-center distance of the centroids of the contacting portions, is selected to align the respective contact portions with respective probe pads on a DUT that is to be tested. Conductive traces 92, 94 affixed to a surface of the substrate conductively interconnect the probe contacts with the conducting portions of the supporting coaxial cable or waveguide. Preferably the conductive traces are affixed to the upper surface of the substrate. As disclosed by Gleason et al., conductive vias passing through the substrate may be used to interconnect the contacts and other conductors on the lower surface of the substrate with the conductive traces affixed to the upper surface. The exemplary probe tip comprises a central signal contact 84 which is interconnected with the central conductor 96 of the coaxial cable 76. In addition to the signal contact, the exemplary probe tip 80 includes a pair of ground contacts 85, 86 that are spaced to either side of the signal contact for engaging probe pads of the DUT that are connected to the DUT's ground plane. The ground contacts are interconnected with an outer conductor 98 of the coaxial cable. The exemplary probe tip may also comprise a planar conductive shield 98 which is substantially coextensive with the lower surface of the substrate and which is also interconnected with the ground contacts and the outer conductor of the coaxial cable. The lateral, linear array of contacts comprising a ground contact 85, 86 spaced to either side of a signal contact 84, known as a ground-signal-ground (GSG) contact arrangement, and is commonly used because it provides good isolation of electromagnetic fields proximate the probe pads. Other exemplary probe contact arrangements comprising a plurality of probe contacts spaced apart by a pitch along a longitudinal axis include a ground-signal (GS) contact arrangement, comprising a single ground contact space apart from a single signal contact; a ground-signal-ground-signal-ground (GSGSG) contact arrangement; a ground-signal-signal-ground (GSSG) contact arrangement; and a signal-ground-signal (SGS) contact arrangement.

Gleason et al., U.S. Pat. No. 6,256,882, illustrates a second type of wafer probe comprising a plurality, sometimes 100 or more, contacts fabricated on a surface of a resilient membrane. The opposite surface of the membrane is supported by a movable block that enables the contacts to be positioned relative to the probe pads of a plurality of DUTs on a wafer and pressed into engagement with the probe pads. Conductive traces on a surface of the membrane interconnect the contacts with the test instrumentation. Similarly, needle probe card type probing systems may comprise many contacts for probing a plurality of DUTs with a single contact with the wafer. The contacts comprise the ends of respective conductive needles. The needles are arranged so that the contacts can be brought into pressing engagement with probe pads on a DUT. The needles are conductively interconnected with the test instrumentation. The contacts of membrane probes and needle probes are typically connected as a plurality of groups of contacts, each containing a plurality of contacts which are typically arranged in contact arrangements, such as one of the exemplary contact arrangements. A plurality of DUTs having probe pads with a corresponding arrangement can be probed during a single contact with the wafer.

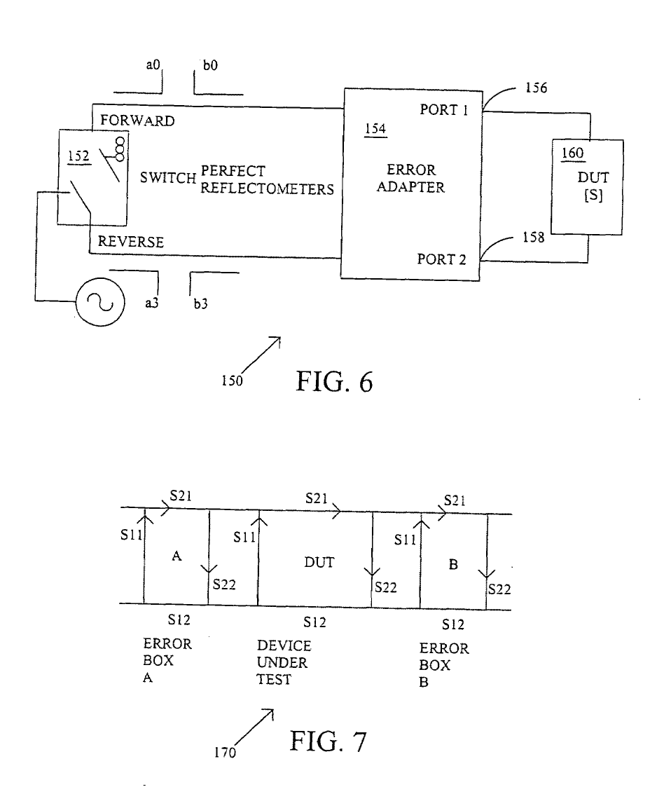

When measuring the performance of electrical networks at frequencies greater than 1 gigahertz, the more accurate measurements commonly employ vector error corrections, such as those commonly implemented in a Vector Network Analyzer (VNA). A probing system that includes a VNA 56 is calibrated to correct for systematic errors in the measurement system and to define a reference plane that specifies where the probe measurement system ends and where the DUT begins. Systematic errors are the result of the non-ideal natures of the VNA itself, and the cables, waveguides and probes that are used to conductively connect the VNA to the DUT. A probing system that includes a VNA is typically calibrated by bringing the contacts of the probe into contact with impedance elements of one or more calibration standards, electrical networks having known or partly known characteristics; stimulating the respective standard; and measuring the response. A difference between the expected response to the stimulation and the actual response enables application of a mathematical correction to subsequent measurements and accurate determination of a DUT's properties. Referring to FIG. 6, the calibrated probe measurement system 150 can be characterized as an ideal VNA 152 with an error adapter network 154 that models the probing system's non-ideal characteristics, as determined by the calibration, that interconnects the ideal VNA to a DUT 160.

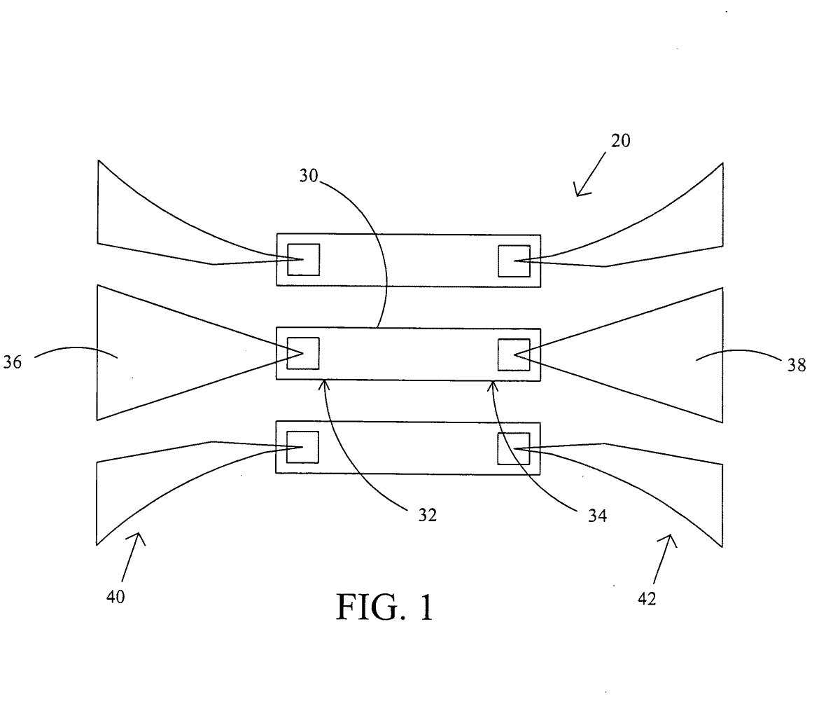

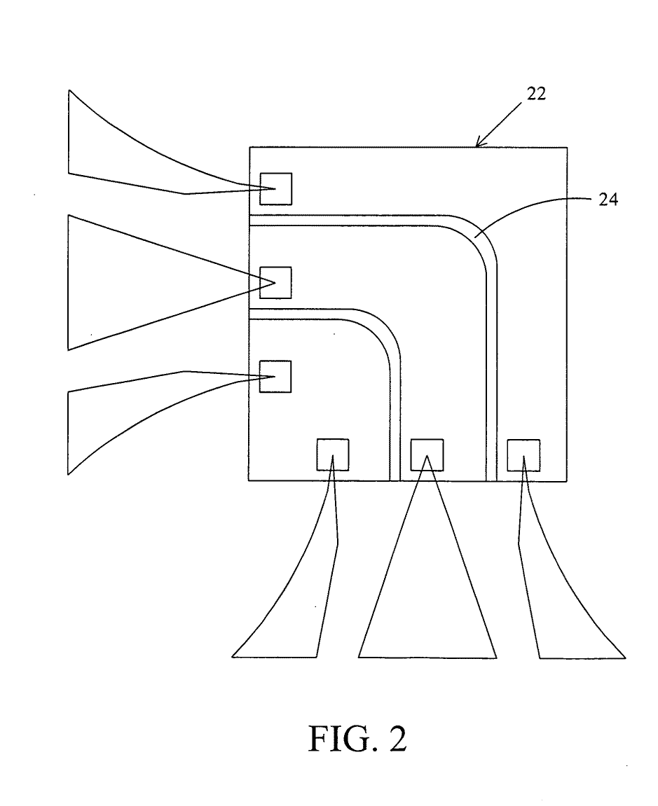

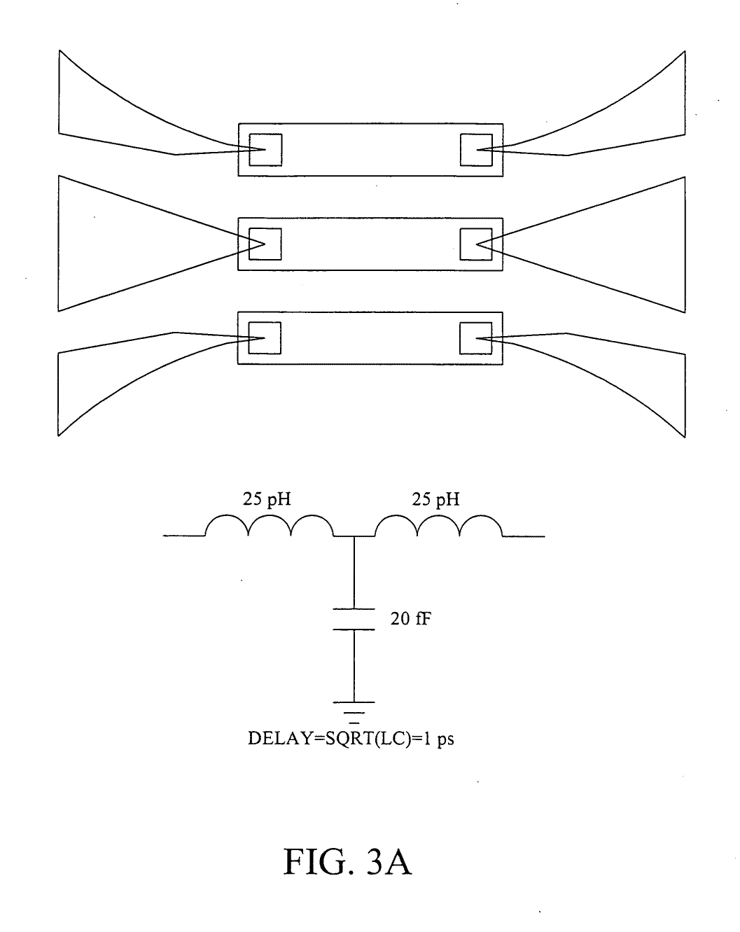

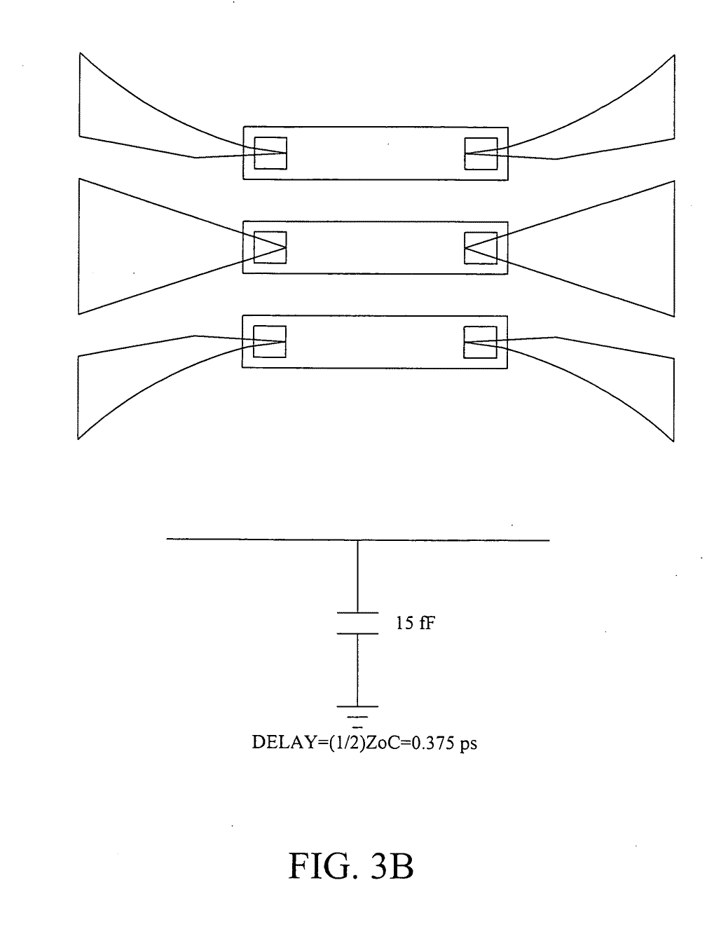

The Short-Open-Load-Thru (SOLT) calibration technique, named for the particular set of calibration standards used in the calibration is the most commonly used VNA calibration technique. However, SOLT technique, as well as the Line-Reflect-Match (LRM) technique and the Thru-Reflect-Line (TRL) technique require a well behaved Thru standard. Referring to FIG. 1, an exemplary Thru calibration standard 20 comprises a 50 ohm transmission line 30 with a specific loss and delay characteristics having a pair of ports or terminal areas 32, 34 engageable by the signal contacts 36, 38 of two probes 40, 42. A well behaved Thru is relatively easy to satisfy if the DUT has ports on opposing sides of the device such as illustrated in FIG. 1. However, if the probe pads are arranged orthogonally a well characterized CPW thru is very difficult to fabricate.

The inventors realized that the problem of a well behaved Thru could be avoided with a Short-Open-Load-Reciprocal (SOLR) calibration technique, comprising a pair of one port Short-Open-Load (SOL) calibrations, because the technique does not require a known Thru standard. As the name suggests the only requirement of the Thru standard in this technique is that the Thru is reciprocal, that is the scattering parameters S₁₂=S₂₁ are for ports having equal impedance. In the SOLT, LRM, and TRL calibrations the Thru standard is typically defined as:

$$S = [ \begin{matrix}0 & {e}^{- γ \cdot l} \\ {e}^{- γ \cdot l} & 0\end{matrix} ]$$

where y and l denote the propagation constant and length of the transmission line of the standard. In particular, SOLT uses the Thru to calculate the port match and transmission terms based on a three-measurement port system.

The need for a known Thru definition is eliminated in SOLR by using the switching terms of a four-measurement port system to calculate the load match error coefficients. This eight-term error model 170 for SOLR is the same as in TRL and LRM family of calibration techniques and is shown in FIG. 7. This error model has eight unknowns although only seven are fully determined to complete the calibration (since S-parameters are ratios). The error box terms S₁₁, S₂₂, S₁₂ and S₂₁ are determined from the one-port Short-Open-Load (SOL) standard measurements which are similar to the SOLT approach. Hence, in an actual one-port measurement the results for SOLT and SOLR should be identical. The relationships between the S₁₂ and S₂₁ terms is determined from the reciprocal standard.

When the DUT is replaced by the reciprocal standard the measured overall S-parameters are given by the signal flow graph. The forward and reverse transmission measurements are then:

S_{21,m}=S_{21,a}·S_{21,r}·S_{21,b}/denominator

S_{12,m}=S_{12,a}·S_{12,r}·S_{12,b}/denominator

where the m, a, b, and r denote measured, error box a, error box b, and reciprocal standard, respectively. The denominator is the same for both measurements and consists of the second-order loop terms for the flow diagram and can be calculated.

The ratio of the measured transmission terms then gives an equation involving only the S₁₂ and S₂₁ terms of the error boxes:

$$\frac{{S}_{21 , m}}{{S}_{12 , m}} = \frac{{S}_{21 , a} \cdot {S}_{21 , b}}{{S}_{12 a} \cdot {S}_{12 , b}}$$

The term, when combined with the products obtained from the two SOL one-port calibrations, provides enough information to complete the two-port calibration. The SOLR derivation shows that the definition of the Thru is not required for the calculation of the error box terms. This characteristic of the SOLR calibration technique is particularly useful for calibrating probing systems that utilize probe cards with a plurality of probe tips and probe systems utilizing orthogonally arranged probes because the ports of the DUTs may be physically distant or may require angled Thru connections because the technique only requires a reciprocal Thru calibration standard.

While the SOL and SOLR calibration techniques avoid the problem of a poorly behaving Thru when calibrating a probing system, the accuracy of the calibration can be significantly effected by the orientation of the probe contacts relative to the impedance element of a calibration standard. A Short or Load calibration standard typically comprises a planar impedance element that is usually fabricated on the wafer that includes the devices to be tested or on a separate impedance standard substrate (ISS) 82. An ISS may be secured to an auxiliary chuck 84 of the probe station to facilitate moving the contacts of the probe for engagement with the impedance element(s) 86 of the calibration standard by operation of the −X,−Y,−Z positioning mechanism of the probe station. For example, the position of probe contacts relative to the edge of a shorting bar, the impedance element of a Short calibration standard, significantly effects the short's inductance and the position of the reference plane as determined by the calibration. However, the inventors observed that when probe tips are moved farther away from the boundaries of the shorting bar the short inductance asymptotically approaches a value that is independent of the alignment of the probe tips relative to the boundaries of the impedance element. Moreover, the inductance is repeatable and can be used as a reference standard in calibration.

The inventors concluded that Short-Open-Load (SOL) and Short-Open-Load-Reflect (SOLR) VNA calibrations will be more tolerant of variability in probe alignment if the planar conductive and resistive areas of the Short and Load calibration standards has a first or longitudinal dimension 102 (substantially normal to the contact axis 90) that is at least twice the pitch of the probe contacts and a second or lateral dimension 104 (substantially parallel to the contact axis) that is at least twice the sum of the pitches of the probe's contacts. For example, referring FIG. 5, the preferred dimensions of the impedance elements of Short and Load calibration standards are at least about two times the pitch in the direction of normal to the contact axis 90 and four times the pitch (2×2P) in the direction parallel to the contact axis of the probe for a probe with three equally spaced probe contacts 84, 85, 86, for example a probe having the common ground-signal-ground contact arrangement. By way of further example, the preferred minimum dimensions of the impedance element of a calibration substrate for use with a probe having four probe tips (for example, ground-signal-signal-ground) are a 2× pitch normal to the contact axis and 6× pitch (2×3P) parallel to the contact axis.

When engaged by the probe contacts, the conductive impedance element 106 or shorting bar of a Short calibration standard short circuits the signal contact(s) and the ground contact(s) of a probe with very low resistance conductive connection. The shorting bar may comprise, for example, a planar deposition of gold or another conductor having a very low resistance.

When engaged by the probe contacts, the conductive impedance element 106 of a Load calibration standard interconnects the signal contact(s) and ground contact(s) of a probe with conductive path having a desired resistance. The desired resistance is typically 50 ohms (Ω) but a different value of resistance may be desired for calibrating a particular probing system. The impedance element may be a substantially uniform planar conductor having a substantially constant resistance between equally spaced points at a plurality of locations on the surface of the impedance element. On the other hand, the value of resistance may vary, for example in a gradient, across an impedance element enabling calibration with different loads by moving the probe on the element. In addition, calibration standards comprising a plurality of elements 106, 108 having differing resistance, for example, 50Ω and “short,” may be produced on the same substrate 110 enabling more than calibration measurement by moving the probe between impedance elements on the same substrate.

Alternative calibration configurations that make use of unpatterned material layers may be used. As opposed to using short, open, and load terminations for elements of calibration standards, any three known impedances may likewise be used to create a one-port calibration. For example, useful combinations may consist of two different sheet resistances and an open, or two different sheet resistances and a short, or three different sheet resistances. In addition, material later that create other known impedances, such as capacitance or inductance, may be used for calibration or for calibration verifications. By way of example, a thin insulating layer with a high dielectric constant layer over a conductive layer may provide a capacitive element.

Preferably the planar impedance regions of the calibration substrate are unpatterned or substantially unpatterned. That is, a conductive surface exists over substantially 100% of the area of the calibration standard that comprises impedance element. Alternatively, to tailor the impedance, the impedance element may be patterned with one or more conductive or non-conductive surface areas 112 preferably smaller than the contact areas of the probe contacts. Under some circumstances it is desirable to have regularly patterned structures, such as meshes, hexagons, chevrons, or fractals, to modify the impedances. Such patterned layers are equivalent to unpatterned layers if the patterns are unrelated to the probe tip contact patterns. Preferably, the patterned layers are selected in such a manner that together with particular probes, a desirable impedance and measurement characteristic results. Alignment keys 114 may be located adjacent to an impedance element to facilitate alignment of the probe contacts and the impedance element. The surface of an impedance element may have a low roughness to reduce wear when engaged by the probe contacts and may be coated with a non-oxidizing or self-passivating film to provide low, repeatable resistance when engaged.

The regularly patterned structures may be based upon the anticipated probe tip pitch. In some cases, the longitudinal dimension of the patterned structure (substantially normal to the contact axis) that is less than twice the pitch of the probe contacts and a second or lateral dimension (substantially parallel to the contact axis) that is less than twice the sum of the pitches of the probe's contacts. In some cases, the longitudinal dimension of the patterned structure (substantially normal to the contact axis) is less than twice the width of the probe tip area and a second or lateral dimension (substantially parallel to the contact axis) that is less than twice the width of the probe tip area. In this manner, independent of the placement of the probe tips contact will be made with the patterned structure. The contact portion for a test socket is generally around 100 microns wide, while the contact portion for a conventional wafer probe is generally around 10-30 microns wide, while the contact portion for small contact wafer probe is generally less than 5 microns wide. In some cases, the conductive material may only cover 10% to 50% of the surface area.

Traditionally it has been thought that for high frequency probing and/or calibration, such as above 1 GHz, a resistive layer would not have a sufficiently stable contact resistance and/or a sufficiently low contact resistance for accurate testing. It was surprising to determine, when making measurements using resistive material, such as NiCr approximately 20 nm thick deposited on a 99% alumina substrate, that it was sufficiently stable and had sufficiently low contact resistance for effective probing and/or calibration. Also, since the resulting measured resistance between the probe tips is dependent upon the tip area, pattern of the probe tips, and the spacing between the probe tips, together with microwave frequency calibration requiring known impedances, it is preferred that a direct current (or otherwise a relatively low frequency) resistance is measured. The direct current (or otherwise a relatively low frequency) may be used as a model for the resistance of the load element for calibration, and this model may be determined each time the probe tips are brought into contact with the unpatterned calibration region. In general, the contact resistance should preferably be less than 5 ohms, preferably less than 10 ohms, and preferably less than 20 ohms at direct current frequencies, or greater than 2 GHz, greater than 20 GHz, and/or greater than 50 GHz. At higher frequencies, such as above 20 or 50 GHz, the probe tip spacing may become a significant portion of the wavelength, together with other reactive effects of the load element. These reactive effects may be characterized for the calibration, by comparing their impedances with other known calibration elements.

A Short-Open-Load (SOL) calibration of a VNA comprises the steps of measuring the result of a stimulation of a Short calibration standard, measuring the result of a stimulation of an Open calibration standard, measuring the result of a stimulation of a Load calibration standard and using the results of the stimulations of the various calibration standards to formulate an error model for the probing system. The calibration can be made more tolerant of variation in the position of the probe contacts on a calibration standard if the impedance element of at least one of the Short calibration standard and the Load calibration standard has a dimension, measured substantially parallel to the contact axis of the probe, that is at least twice the combined pitches of the probe contacts and a dimension, measured substantially normal to the contact axis, that is at least twice the pitch of the contacts. A two-port calibration (SOLR) that does not require a well behaved Thru can be accomplished by adding a reciprocal calibration to the SOL calibration. The reciprocal calibration utilizes an error model developed by stimulating the transmission line of a Thru with a signal transmitted from a first probe at a first port or terminal and then by stimulating the Thru with signal transmitted from a second probe at the second port or terminal the Thru calibration standard.

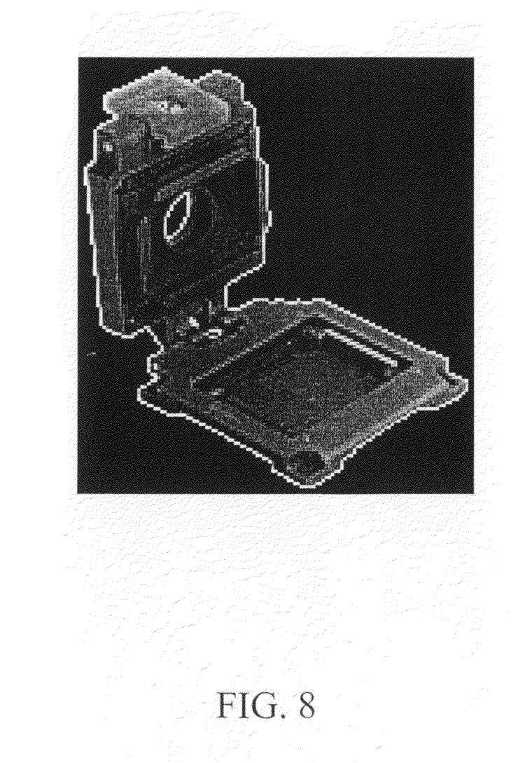

While the generally un-patterned layers are useful for calibrating probes, it turns out that such structures are likewise suitable for calibrating test contactors (sockets) for packaged integrated circuits. For example, several such integrated circuit test sockets are available from Gryphics among other companies. FIG. 8 illustrates an exemplary integrated circuit test socket. In general, the test sockets typically include a housing that is supported by a circuit board. The housing of the test socket generally includes conductive interconnects which interconnect a packaged integrated circuit with the circuit board. Depending upon the particular test socket, a cover member may be used to assist maintaining the packaged integrated circuit within the housing. In this manner, the packaged integrated circuit may be maintained in a housing electrically interconnected with the circuit board. Electrical signals may be transmitted to and from the integrated circuit for testing the integrated circuit and otherwise providing interconnection between the integrated circuit and other electronics.

For test sockets the generally unpatterned calibration element layers may be trimmed to the general size of the surface mount package being tested. This general trimming facilitates mechanical clearances, albeit not necessary for electrical functionality. Three or more different such substrates may be sequentially inserted into the test socket, preferably in a sequence analogous to contacting the wafer probe for calibration, so that calibration of the test socket may be effectuated. Typically, the substrates are inserted within the test socket with the “active” side in connection with the interconnects and the test signals being provided from the outside of the test socket to the substrates. In some cases, the substrates may be positioned with the “active” side in connection with the outside of the test socket, with the test signals being provided from the “inside” of the test socket. In either case, the calibration structures may be used to calibrate or characterize the test socket. In some cases, the calibration substrates may be included merely along the positions proximate the location of the interconnects. In the case that the interconnects are around the general periphery of the test socket, the substrates may only generally have the calibration regions around the general periphery of the test socket.

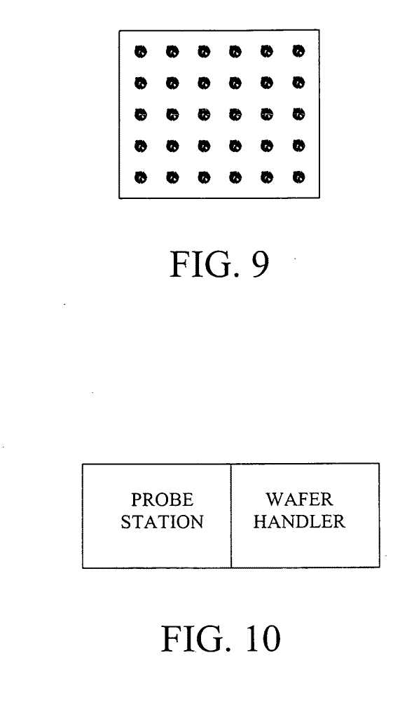

Referring to FIG. 9, in some cases, such as for insertion into test sockets, it may be advantageous to pattern small conductor pads in the unpatterned resistive layer at locations where the probe tips or socket pins would come into contact. Such pads facilitate reliable, consistent, and durable contact to a known probe or socket footprint. For example, a set of calibration substrates could use contact pads in the positions of package pads, without the need to customize the calibration patterns to the ground or signal designations of each package pin. In cases with contact pads, it still may be desirable to characterize the resulting resistance of each calibration element, since the resistance will change with the impedances of other probe tips that connect with the layer.

Referring to FIG. 10, auto-probing probe stations typically include a wafer handling capability to automatically insert and remove wafers without the operator having to do it manually. With auto-probing probe stations it is desirable that the probes are calibrated for accurate measurements. Moreover, it is desirable that the probes are calibrated as mounted in the auto probing probe stations, so that the calibrations more accurately reflect the subsequent measurements. For auto-probing probe stations, the calibration substrate is preferably included as part of a wafer which is otherwise suitable for being handled by the auto probing probe station. By way of example, a wafer may be included with one or more calibration regions. In some cases, auto-probing probe stations do not include a calibration chuck.

In one example, a set of three different calibration wafers may be included with a suitable resistive, conductive, or otherwise characteristic suitable for calibration at the probe tips. In this manner, with sequential characterization using each of the calibration wafers, a calibration at the probe tips may be performed. In another example, a calibration wafer may include multiple calibration regions, each with different electrical characteristics.

In another example, the calibration wafer may have one or more different regions of generally resistive material and conductive material. In this manner, the probes may be calibrated by coming into contact with different calibration regions of the wafer.

In another example, one wafer may be used with one or more regions of generally resistive material. A conductive block of material may be included with the auto-probing probe station such that the conductivity and/or contact resistance of the probes may be determined.

The detailed description, above, sets forth numerous specific details to provide a thorough understanding of the present invention. However, those skilled in the art will appreciate that the present invention may be practiced without these specific details. In other instances, well known methods, procedures, components, and circuitry have not been described in detail to avoid obscuring the present invention.

It is to be understood that in addition to calibrating sockets, the techniques described herein may likewise be used for calibrating membrane based probes or otherwise probe cards.

All the references cited herein are incorporated by reference.

The terms and expressions that have been employed in the foregoing specification are used as terms of description and not of limitation, and there is no intention, in the use of such terms and expressions, of excluding equivalents of the features shown and described or portions thereof, it being recognized that the scope of the invention is defined and limited only by the claims that follow.

I (we) claim:

1. A method for calibrating a probing system including a probing element comprising a first contact and a second contact spaced apart from said first contact by a pitch on a contact axis, said method comprising the steps of:
(a) measuring a result of a stimulation of a first calibration standard with a signal, said first calibration standard comprising a short circuit between said first contact and said second contact;
(b) measuring a result of a stimulation of a second calibration standard with a signal, said second calibration standard comprising an open circuit between said first contact and said second contact;
(c) measuring a result of a stimulation of a third calibration standard with a signal, said third calibration standard comprising a substantially planar resistor having a surface simultaneous engageable by said first contact and said second contact, said planar resistance element having a first dimension, measured approximately parallel to said contact axis, of at least twice said pitch and a second dimension, measured substantially normal to said contact axis, of at least twice said pitch; and
(d) using said result of said stimulation of said first calibration structure, said result of said stimulation of said second calibration structure, and said result of said stimulation of said third calibration structure to formulate an error model for said probing system.

2. The method for calibrating a probing system of claim 1 wherein a resistance between two points separated by a distance equal to said pitch at a first location on said surface of said resistance element is substantially equal to a resistance between two points separated by a distance equal to said pitch at a second location on said surface of said resistance element.

3. The method for calibrating a probing system of claim 1 wherein a resistance between two points separated by a distance equal to said pitch at a first location on said surface of said resistance element is substantially different than a resistance between two points separated by a distance equal to said pitch at a second location on said surface of said resistance element.

4. The method for calibrating a probing system of claim 1 wherein said surface of said resistance element comprises at least one non-conductive region having an area less than an area of said first contact.

5. The method for calibrating a probing system of claim 1 wherein the surface of said first calibration region having an area less than an area of said first contact.

6. The method for calibrating a probing system of claim 1 wherein the surface said first calibration region is patterned.

7. The method for calibrating a probing system of claim 1 wherein said planar resistance element is affixed to a surface of a substrate and said first calibration standard comprises a substantially planar conductive element affixed to said surface of said substrate.

8. The method for calibrating a probing system of claim 1 wherein said first calibration standard comprises a substantially planar conductive element having a first dimension of at least twice said pitch measured approximately parallel to said contact axis and a second dimension at least twice said pitch measured substantially normal to said contact axis.

9. The method for calibrating a probing system of claim 1 further comprising the steps of:
(a) measuring a result of a first stimulation of a fourth calibration standard by a signal transmitted from said first contact of said probe, said fourth calibration standard comprising a path having first terminal engageable by said first contact of said probe and a second terminal engageable by a contact of a second probe;
(b) measuring a result of a second stimulation of said fourth calibration standard by a signal transmitted from said contact of said second probe; and
(c) using said result of said first stimulation of said fourth calibration standard, said second stimulation of said fourth calibration standard, said result of said stimulation of said first calibration structure, said result of said stimulation of said second calibration structure, and said result of said stimulation of said third calibration structure to formulate another error model for said probing system.

10. The method for calibrating a probing system of claim 9 wherein a resistance between two points separated by a distance equal to said pitch at a first location on said surface of said resistance element is substantially equal to a resistance between two points separated by a distance equal to said pitch at a second location on said surface of said resistance element.

11. The method for calibrating a probing system of claim 9 wherein a resistance between two points separated by a distance equal to said pitch at a first location on said surface of said resistance element is substantially different than a resistance between two points separated by a distance equal to said pitch at a second location on said surface of said resistance element.

12. The method for calibrating a probing system of claim 9 wherein said planar resistance element is affixed to a surface of a substrate and said first calibration standard comprises a substantially planar conductive element affixed to said surface of said substrate.

13. The method for calibrating a probing system of claim 9 wherein said first calibration standard comprises a substantially planar conductive element having a first dimension of at least twice said pitch measured approximately parallel to said contact axis and a second dimension at least twice said pitch measured substantially normal to said contact axis.

14. A method for calibrating a probing system including a probing element comprising at least three contacts, including a signal contact and a ground contact, spaced along a contact axis, each contact separated from an adjacent contact by a pitch, said method comprising the steps of:
(a) measuring a result of a stimulation of a first calibration standard with a signal transmitted from said signal contact, said first calibration standard comprising a short circuit between said signal contact and said ground contact;
(b) measuring a result of a stimulation of a second calibration standard with a signal transmitted from said signal contact, said second calibration standard comprising an open circuit between said signal contact and said ground contact;
(c) measuring a result of a stimulation of a third calibration standard with a signal transmitted from said signal contact, said third calibration standard comprising a substantially planar resistance element having a surface simultaneous engageable by said signal contact and said ground contact, said planar resistance element having a first dimension, measured approximately parallel to said contact axis, of at least twice a sum of said pitches separating said contacts of said probe and a second dimension, measured substantially normal to said contact axis, at least twice said pitch; and
(d) using said result of said stimulation of said first calibration structure, said result of said stimulation of said second calibration structure, and said result of said stimulation of said third calibration structure to formulate an error model for said probing system.

15. The method for calibrating a probing system of claim 14 wherein a resistance between two points separated by a distance equal to said pitch at a first location on said surface of said resistance element is substantially equal to a resistance between two points separated by a distance equal to said pitch at a second location on said surface of said resistance element.

16. The method for calibrating a probing system of claim 14 wherein a resistance between two points separated by a distance equal to said pitch at a first location on said surface of said resistance element is substantially different than a resistance between two points separated by a distance equal to said pitch at a second location on said surface of said resistance element.

17. The method for calibrating a probing system of claim 14 wherein said planar resistance element is affixed to a surface of a substrate and said first calibration standard comprises a substantially planar conductive element affixed to said surface of said substrate.

18. The method for calibrating a probing system of claim 14 wherein said first calibration standard comprises a substantially planar conductive element having a first dimension, measured approximately parallel to said contact axis, of at least twice a sum of said pitches separating said contacts of said probe and a second dimension, measured substantially normal to said contact axis, at least twice said pitch.

19. The method for calibrating a probing system of claim 14 further comprising the steps of:
(a) measuring a result of a first stimulation of a fourth calibration standard by a signal transmitted from said signal contact of said probe, said fourth calibration standard comprising a path having first terminal engageable by said signal contact of said probe and a second terminal engageable by another signal contact of the probing element;
(b) measuring a result of a second stimulation of said fourth calibration standard by a signal transmitted from said another signal contact of said probe; and
(c) using said result of said first stimulation of said fourth calibration standard, said second stimulation of said fourth calibration standard, said result of said stimulation of said first calibration structure, said result of said stimulation of said second calibration structure, and said result of said stimulation of said third calibration structure to formulate another error model for said probing system.

20. The method for calibrating a probing system of claim 16 wherein a resistance between two points separated by a distance equal to said pitch at a first location on said surface of said resistance element is substantially equal to a resistance between two points separated by a distance equal to said pitch at a second location on said surface of said resistance element.

21. The method for calibrating a probing system of claim 16 wherein a resistance between two points separated by a distance equal to said pitch at a first location on said surface of said resistance element is substantially different than a resistance between two points separated by a distance equal to said pitch at a second location on said surface of said resistance element.

22. The method for calibrating a probing system of claim 16 wherein said planar resistance element is affixed to a surface of a substrate and said first calibration standard comprises a substantially planar conductive element affixed to said surface of said substrate.

23. The method for calibrating a probing system of claim 16 wherein said first calibration standard comprises a substantially planar conductive element having a first dimension, measured approximately parallel to said contact axis, of at least twice a sum of said pitches separating said contacts of said probe and a second dimension, measured substantially normal to said contact axis, at least twice said pitch.

24. A method for calibrating a probing system comprising a first contact and a second contact spaced apart from said first contact by a pitch on a contact axis, said method comprising the steps of:
(a) measuring a result of a stimulation of a first calibration standard with a signal, said first calibration standard comprising a first electrical element between said first contact and said second contact;
(b) measuring a result of a stimulation of a second calibration standard with a signal, said second calibration standard comprising a second electrical element between said first contact and said second contact;
(c) measuring a result of a stimulation of a third calibration standard with a signal, said third calibration standard comprising a substantially planar resistor having a surface simultaneous engageable by said first contact and said second contact, said planar resistance element having a first dimension, measured approximately parallel to said contact axis, of at least twice said pitch and a second dimension, measured substantially normal to said contact axis, of at least twice said pitch;
(d) using said result of said stimulation of said first calibration structure, said result of said stimulation of said second calibration structure, and said result of said stimulation of said third calibration structure to formulate an error model for said probing system;
(e) wherein said planar resistance element has a contact resistance less than 20 ohms at zero frequency or greater.

25. The system of claim 24 wherein said contact resistance is less than 10 ohms.

26. The system of claim 25 wherein said contact resistance is less than 5 ohms.

27. The system of claim 24 wherein said contact resistance is at 2 GHz or greater.

28. The system of claim 24 wherein said contact resistance is at 20 GHz or greater.

29. The system of claim 24 wherein said contact resistance is at 50 GHz or greater.

30. The system of claim 26 wherein said contact resistance is at 2 GHz or greater.

31. The system of claim 26 wherein said contact resistance is at 20 GHz or greater.

32. The system of claim 26 wherein said contact resistance is at 50 GHz or greater.

33. A method for calibrating a probing system comprising a first contact and a second contact spaced apart from said first contact by a pitch on a contact axis, said method comprising the steps of:
(a) measuring a result of a stimulation of a first calibration standard with a signal, said first calibration standard comprising a first electrical element between said first contact and said second contact wherein said first electrical element is a generally unpatterned layer;
(b) measuring a result of a stimulation of a second calibration standard with a signal, said second calibration standard comprising a second electrical element between said first contact and said second contact wherein said second electrical element is a generally unpatterned layer;
(c) measuring a result of a stimulation of a third calibration standard with a signal, said third calibration standard comprising a substantially planar resistor having a surface simultaneous engageable by said first contact and said second contact, said planar resistance element having a first dimension, measured approximately parallel to said contact axis, of at least twice said pitch and a second dimension, measured substantially normal to said contact axis, of at least twice said pitch, wherein said resistance element is a generally unpatterned layer;
(d) using said result of said stimulation of said first calibration structure, said result of said stimulation of said second calibration structure, and said result of said stimulation of said third calibration structure to formulate an error model for said probing system.

34. The system of claim 33 wherein at least one of said unpatterned layers includes patterned structures that are independent of said pitch.

35. The system of claim 33 wherein said system includes a test socket.

36. The system of claim 35 wherein at least one of said unpatterned layers includes a generally rectangular region of at least one of said first electrical element, said second electrical element, and said resistance element.

37. The system of claim 33 wherein said resistive element includes conductive elements located in such a manner that they are coincident with said first and second contacts.

38. The system of claim 37 wherein said conductive elements are located in such a manner that are coincident with ten such said contacts.

39. The system of claim 33 wherein one of said first, second, and third calibration structures is supported by a wafer.

40. The system of claim 39 wherein at least two of said first, second, and third calibration structures are illustrated by a single wafer.
